(19) United States
(12) Patent Application Publication
(10) Pub. No.: US 2025/0304826 A1
(43) Pub. Date: Oct. 2, 2025

(54) POLISHING COMPOSITION AND POLISHING METHOD

(71) Applicant: FUJIMI INCORPORATED, Kiyosu-shi (JP)

(72) Inventors: Kazuki YAGI, Kiyosu-shi (JP); Keita SUZUKI, Kiyosu-shi (JP)

(73) Assignee: FUJIMI INCORPORATED, Kiyosu-shi (JP)

(21) Appl. No.: 19/089,528

(22) Filed: Mar. 25, 2025

(30) Foreign Application Priority Data
Mar. 26, 2024 (JP) 2024-050409

(51) Int. Cl. C09G 1/02

(52) U.S. Cl. CPC C09G 1/02

(57) ABSTRACT

There are provided a polishing composition and a polishing method that enable high-speed polishing of simple-substance silicon under acidic conditions. A polishing composition for polishing simple-substance silicon contains: abrasives; and an adsorbing compound, in which, the pH is 1 or more and 6 or less, when a substrate having a surface containing simple-substance silicon is subjected to polishing of the surface using an aqueous solution containing the adsorbing compound and water, and then the adhesion force of the abrasives to the surface of the polished substrate and the coverage of the adsorbing compound are measured, a value obtained by multiplying the adhesion force and the coverage is more than 50 and less than 100, the adhesion force is attachment strength between the abrasives and the surface of the substrate calculated by the force curve measurement using a probe provided in an atomic force microscope, the probe contains the same material as that of the abrasives and has a tip portion having the same radius of curvature as that of the abrasives, and the coverage is the ratio of the area of a part covered with the adsorbing compound of the surface of the substrate to the area of the entire surface of the substrate.

### TECHNICAL FIELD

The present invention relates to a polishing composition and a polishing method.

### BACKGROUND ART

In recent years, with the multilayer wiring on the surface of a semiconductor substrate, a so-called chemical mechanical polishing (CMP) technology of polishing and flattening a semiconductor substrate is utilized in producing a device. The CMP is a method for flattening the surfaces of objects to be polished (polishing targets), such as a semiconductor substrate, using a polishing composition (slurry) containing abrasives of silica, alumina, ceria, and the like, an anticorrosive agent, a surfactant, and the like. The objects to be polished (polishing targets) are, for example, silicon, polysilicon, silicon oxide, silicon nitride, wiring and plugs containing metals and the like.

High-speed polishing of simple-substance silicon, such as silicon monocrystal, polysilicon, and amorphous silicon, is performed with a highly alkaline polishing composition. However, as described above, the surface of the semiconductor substrate has various kinds of objects to be polished. Therefore, the polishing of films of other species, such as a silicon oxide film and a silicon nitride film, and the simple-substance silicon at the same time requires polishing using an acidic polishing composition.

### SUMMARY

### Technical Problem

Thus, a method for improving the polishing removal rate for the simple-substance silicon even when an acidic polishing composition is used has been desired.

The present invention has been made in view of the above-described circumstances. It is an object of the present invention to provide a polishing composition and a polishing method that enable high-speed polishing of the simple-substance silicon under acidic conditions.

### Solution to Problem

A polishing composition according to one aspect of the present invention, which is a polishing composition for polishing simple-substance silicon, contains: abrasives; and an adsorbing compound, in which, the pH is 1 or more and 6 or less, and, when a substrate having a surface containing simple-substance silicon is subjected to polishing of the surface using an aqueous solution containing the adsorbing compound and water, and then the adhesion force of the abrasives to the surface of the polished substrate and the coverage of the adsorbing compound are measured, a value obtained by multiplying the adhesion force and the coverage is more than 50 and less than 100. The adhesion force is attachment strength between the abrasives and the surface of the substrate calculated by the force curve measurement using a probe provided in an atomic force microscope. The probe contains the same material as that of the abrasives and has a tip portion having the same radius of curvature as that of the abrasives. The coverage is the ratio of the area of a part covered with the adsorbing compound of the surface of the substrate to the area of the entire surface of the substrate.

A polishing method according to another one aspect of the present invention is a method for polishing an object to be polished using the polishing composition according to the present invention.

### Advantageous Effects of Invention

The present invention can provide a polishing composition and a polishing method that enable high-speed polishing of the simple-substance silicon under acidic conditions.

### BRIEF DESCRIPTION OF DRAWINGS

FIG. 1 is a graph showing, in polishing compositions according to the present invention, the correlation between the value obtained by multiplying the adhesion force with the coverage and the polishing removal rate for polysilicon for each of the types and the concentrations of the adsorbing compounds contained in the polishing compositions.

### DESCRIPTION OF EMBODIMENTS

Hereinafter, one embodiment of the present invention is described. The embodiment described below gives one example of the present invention, and the present invention is not limited to the embodiment. The embodiment described below can be variously altered or improved, and such altered or improved aspects can also be included in the present invention.

### <Polishing Composition>

A polishing composition, which is a polishing composition for polishing simple-substance silicon, contains abrasives and an adsorbing compound, in which, the pH is 1 or more and 6 or less, and, when a substrate having a surface containing simple-substance silicon is subjected to polishing of the surface using an aqueous solution containing the adsorbing compound and water, and then the adhesion force of the abrasives to the surface of the polished substrate and the coverage of the adsorbing compound are measured, a value obtained by multiplying the adhesion force and the coverage is more than 50 and less than 100. The adhesion force is attachment strength between the abrasives and the surface of the substrate calculated by the force curve measurement using a probe provided in an atomic force microscope (AFM). The probe contains the same material as that of the abrasives and has a tip portion having the same radius of curvature as that of the abrasives. The coverage is the ratio of the area of a part covered with the adsorbing compound of the surface of the substrate to the area of the entire surface of the substrate.

The present inventors have found that, by the use of the polishing composition containing abrasives and an adsorbing compound, in which, the pH is 1 or more and 6 or less, and, when a substrate having a surface containing simple-substance silicon is subjected to polishing of the surface using an aqueous solution containing the adsorbing compound and water, and then the adhesion force of the abrasives to the surface of the polished substrate and the coverage of the adsorbing compound are measured, a value obtained by multiplying the adhesion force and the coverage is more than 50 and less than 100, the substrate surface is covered with the adsorbing compound and the attachment force of the abrasives to the covered substrate surface falls within an appropriate range for polishing. Therefore, the use of the polishing composition according to this embodiment easily increase the polishing removal rate of the simple-substance silicon under acidic conditions.

### (Abrasives)

The polishing composition according to this embodiment contains abrasives. The abrasives have an action of mechanically polishing an object to be polished. The type of the abrasives contained in the polishing composition according to this embodiment is not particularly limited, and particles containing metal oxides, such as alumina (Al₂O₃), silica (SiO₂), cerium oxide (CeO₂), zirconia (ZrO₂), titania (TiO₂), iron oxide (FeO, Fe₃O₄, Fe₂O₃), and manganese oxide (MnO, Mn₃O₄, Mn₂O₃, MnO₂), can be used, for example. One type of the abrasives may be used alone or two or more types thereof may be used in combination. As the abrasives, commercially available products may be used or synthetic products may be used. Among the abrasives above, alumina and silica are preferable and silica is more preferable.

The type of the silica includes, but is not particularly limited to, colloidal silica, fumed silica, and the like, with colloidal silica being preferable.

A colloidal silica production method includes a soda silicate method and a sol-gel method. Any colloidal silica produced by any production method may be acceptable. However, from the viewpoint of reducing metal impurities, colloidal silica produced by the sol-gel method is preferable. The colloidal silica produced by the sol-gel method is preferable due to a small content of metal impurities or corrosive ions, such as chloride ions, diffusible in semiconductors. The production of the colloidal silica by the sol-gel method can be performed using conventionally known methods. Specifically, the colloidal silica can be obtained by performing a hydrolysis and condensation reaction using a hydrolyzable silicon compound (e.g., alkoxysilane or derivatives thereof) as a raw material.

The colloidal silica may have an anionic group. More specifically, a silica particle may be an anion-modified silica particle or may be anion-modified colloidal silica. The colloidal silica having an anionic group (anion-modified colloidal silica) preferably includes colloidal silica in which an anionic group, such as a carboxylic acid group, a sulfonic acid group, a phosphonic acid group, and an alumic acid group, is immobilized on the surface. A method for producing such colloidal silica having an anionic group includes, but is not particularly restricted to, a method including allowing a silane coupling agent having an anionic group at the end and colloidal silica to react with each other, for example.

As a specific example, when a sulfonic acid group is immobilized on the colloidal silica, the immobilization can be performed by the method described in “Sulfonic acid-functionalized silica through of thiol groups”, Chem. Commun., 246-247 (2003), for example. Specifically, the colloidal silica on the surface of which sulfonic acid is immobilized (sulfonic acid-modified colloidal silica) can be obtained by coupling a silane coupling agent having a thiol group, such as 3-mercaptopropyltrimethoxysilane, to the colloidal silica, and then oxidizing the thiol group with hydrogen peroxide.

When a carboxylic acid group is immobilized on the colloidal silica, the immobilization can be performed by the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000), for example. Specifically, the colloidal silica on the surface of which carboxylic acid is immobilized (carboxylic acid-modified colloidal silica) can be obtained by coupling a silane coupling agent containing photoreactive 2-nitrobenzyl ester to the colloidal silica, followed by light irradiation.

### (Shape of Abrasives)

The shape of the abrasives is not particularly restricted and may be either a spherical shape or a non-spherical shape. Specific examples of the non-spherical shape include, but are not particularly restricted to, various shapes, such as polygonal columnar shapes, such as a triangular column or a square column, a cylindrical shape, a barrel shape in which a center portion of a cylinder is bulged more than an edge portion of the cylinder, a donut shape having a penetrating disk center portion, a plate shape, a so-called cocoon shape having a constriction in a middle portion, a so-called associated type spherical shape in which a plurality of particles are integrated, a so-called konpeito shape having a plurality of protrusions on a surface, a rugby ball shape, and the like.

### (Average Primary Particle Diameter of Abrasives)

The size of the abrasives is not particularly restricted. For example, the average primary particle diameter of the abrasives may be 5 nm or more, may be 8 nm or more, or may be 10 nm or more. With an increase in the average primary particle diameter of the abrasives, the polishing removal rate of the object to be polished with the polishing composition is improved. The average primary particle diameter of the abrasives may be 200 nm or less, may be 150 nm or less, or may be 100 nm or less. With a decrease in the average primary particle diameter of the abrasives, it becomes easier to obtain a surface with fewer defects by polishing using the polishing composition. The average primary particle diameter of the abrasives can be calculated based on the specific surface area (SA) of the abrasives calculated from the BET method, assuming that the shape of abrasives is a perfect sphere, for example. For example, the average primary particle diameter of the abrasives can be calculated from the specific surface area of the abrasives by the BET method measured using “Flow Sorb II 2300” manufactured by Micromeritex and the true density of the abrasives.

### (Average Secondary Particle Diameter of Abrasives)

The average secondary particle diameter of the abrasives is not particularly restricted. For example, the average secondary particle diameter of the abrasives may be 10 nm or more, may be 15 nm or more, or may be 20 nm or more. With an increase in the average secondary particle diameter of the abrasives, the resistance during polishing decreases, enabling more stable polishing. The average secondary particle diameter of the abrasives may be 300 nm or less, may be 200 nm or less, or may be 100 nm or less. With a decrease in the average secondary particle diameter of the abrasives, the surface area per unit mass of the abrasives increases, the frequency of contact with the object to be polished is improved, and the polishing removal rate is further improved. The average secondary particle diameter of the abrasives can be measured by a dynamic light scattering method represented by laser diffraction scattering, for example.

### (Average Degree of Association of Abrasives)

The average degree of association of the abrasives is not particularly restricted. For example, the average degree of association of the abrasives may be 5.0 or less, may be 4.0 or less, or may be 3.0 or less. With a decrease in the average degree of association of the abrasives, defects can be further reduced. The average degree of association of the abrasives may be 1.0 or more, may be 1.5 or more, or may be 2.0 or more. An increase in the average degree of association of the abrasives is advantageous for improving the polishing removal rate of the object to be polished with the polishing composition. The average degree of association of the abrasives is obtained by dividing the value of the average secondary particle diameter of the abrasives by the value of the average primary particle diameter of the abrasives.

### (Concentration of Abrasives)

The concentration of the abrasives in the polishing composition according to this embodiment is not particularly limited, or may be 0.1% by mass or more, may be 1% by mass or more, or may be 3% by mass or more when the abrasive is silica. When the abrasive is silica, the concentration may be 10% by mass or less, may be 8% by mass or less, or may be 6% by mass or less. When the concentration of the abrasives falls within such ranges, a high polishing removal rate can be obtained.

### (Adsorbing Compound)

The polishing composition in one aspect of the present invention contains the adsorbing compound. The adsorbing compound is not particularly restricted and may be at least one of a water-soluble polymer and a surfactant.

When the adsorbing compound is a water-soluble polymer, the type of the water-soluble polymer is not particularly restricted and may be at least one among nonionic, anionic, cationic, and amphoteric water-soluble polymers.

Examples of the nonionic water-soluble polymer include polyvinyl alcohol, polyvinylpyrrolidone, polyacrylamide, poly-N-vinylacetamide, polyethylene glycol, hydroxyethyl cellulose, a butenediol-vinyl alcohol copolymer, and the like.

The anionic water-soluble polymer may have an anionic group. For example, the anionic water-soluble polymer includes polyvinyl sulfonic acid, polystyrene sulfonic acid, polyallyl sulfonic acid, polymethallyl sulfonic acid, poly(2-acrylamide-2-methylpropane sulfonic acid), polyisoprene sulfonic acid, polyacrylic acid, polymethacrylic acid, a (meth)acrylic acid-isoprene sulfonic acid copolymer, a (meth)acrylic acid-[2-(meth)acrylamide-2-methylpropane sulfonic acid]copolymer, a (meth)acrylic acid-isoprene sulfonic acid-[2-(meth)acrylamide-2-methylpropane sulfonic acid]copolymer, carboxymethyl cellulose, and the like. These anionic water-soluble polymers may have the form of a neutralized salt.

Examples of the cationic water-soluble polymer include polyethyleneimine (PEI), polyvinylamine, polyallylamine, polyvinylpyridine, a cationic acrylamide polymer, and the like.

Examples of the amphoteric water-soluble polymer include a copolymer of a vinyl monomer having an anionic group and a vinyl monomer having a cationic group, a vinyl-based amphoteric polymer having a carboxybetaine group or a sulfobetaine group, and the like. Specific examples include an acrylic acid/dimethylaminoethyl methacrylic acid copolymer, an acrylic acid/diethylaminoethyl methacrylic acid copolymer, and the like.

When the adsorbing compound is a surfactant, the type of the surfactant is not particularly restricted and may be at least one among nonionic, anionic, cationic, and amphoteric surfactants.

Examples of the nonionic surfactant include an alkyl ether type, such as polyoxyethylene lauryl ether and polyoxyethylene oleyl ether; an alkyl phenyl ether type, such as polyoxyethylene octyl phenyl ether; an alkyl ester type, such as polyoxyethylene laurate; an alkyl amine type, such as polyoxyethylene lauryl amino ether; an alkyl amide type, such as polyoxyethylene laurate amide; a polypropylene glycol ether type, such as polyoxyethylene polyoxypropylene ether; an alkanol amide type, such as oleic acid diethanol amide; an allyl phenyl ether type, such as polyoxyalkylene allyl phenyl ether, and the like. In addition thereto, propylene glycol, diethylene glycol, monoethanolamine, alcohol ethoxylate, alkylphenol ethoxylate, tertiary acetylene glycol, alkanol amide, and the like can also be used as the nonionic surfactant.

Examples of the anionic surfactant include a carboxylic acid type, such as sodium myristate, sodium palmitate, sodium stearate, sodium laurate, and potassium laurate; a sulfate ester type, such as sodium octyl sulfate; a phosphate ester type, such as lauryl phosphate and sodium lauryl phosphate; a sulfonic acid type, such as sodium dioctyl sulfosuccinate and sodium dodecyl benzene sulfonate; and the like.

Examples of the cationic surfactant include amines, such as laurylamine hydrochloride, and the like.

Examples of the amphoteric surfactant include lecithin, alkyl amine oxide, alkyl betaine, such as N-alkyl-N,N-dimethylammonium betaine, sulfobetaine, and the like.

The adsorbing compound can have at least one selected from the group consisting of a hydroxy group, a carbonyl group, a sulfo group, and an amide group. The adsorbing compound specifically includes a butenediol-vinyl alcohol copolymer (BVOH), polyvinyl alcohol (PVA), polyacrylic acid (PAA), carboxymethyl cellulose (CMC), polystyrenesulfonic acid, poly-N-vinylacetamide, polyvinylpyrrolidone, hydroxyethylcellulose, polyacrylamide, or combinations thereof. The inclusion of such adsorbing compounds in the polishing composition not only improves the polishing removal rate of the simple-substance silicon but further facilitates the adjustment of the adhesion force of the abrasives to the substrate surface.

The concentration of the adsorbing compound contained in the polishing composition may be 30 ppm or more, may be 40 ppm or more, or may be 70 ppm or more. When the concentration of the adsorbing compound is 30 ppm or more, the abrasives easily roll over the substrate surface, and therefore the polishing ability is easily improved.

The concentration of the adsorbing compound contained in the polishing composition may be 2000 ppm or less, may be 1500 ppm or less, may be 500 ppm or less, may be 400 ppm or less, or may be 200 ppm or less. When the concentration of the adsorbing compound is 2000 ppm or less, the abrasives are hardly detached from the substrate surface, and therefore a decrease in polishing ability is easily prevented.

In the polishing composition in the present invention, when a substrate having a surface containing simple-substance silicon is subjected to polishing of the surface using an aqueous solution containing the adsorbing compound and water, and then the adhesion force of the abrasives to the surface of the polished substrate and the coverage of the adsorbing compound are measured, a value obtained by multiplying the adhesion force and the coverage is more than 50 and less than 100. Herein, the adhesion force is attachment strength between the abrasives and the surface of the substrate and the coverage is the ratio of the area of a part covered with the adsorbing compound of the surface of the substrate to the area of the entire surface of the substrate. The adhesion force is affected by the extent to which the substrate is covered with the adsorbing compound when the abrasives come into contact the substrate. More specifically, the value obtained by multiplying the adhesion force and the coverage indicates the ease of detachment of the abrasives on the substrate surface.

The value obtained by multiplying the adhesion force and the coverage may be 55 or more, or may be 60 or more. When the value obtained by multiplying the adhesion force and the coverage is more than 50, the attachment force to the substrate surface of the abrasives is improved and the polishing ability is easily improved. The value obtained by multiplying the adhesion force and the coverage may be 98 or less. When the value obtained by multiplying the adhesion force and the coverage is less than 100, the attachment force to the substrate surface of the abrasives is not excessively high, and therefore such a problem that the abrasives cover the substrate surface, restricting the rolling of the abrasives, hardly occurs.

### (Method for Measuring Adhesion Force and Coverage)

The adhesion force and the coverage of the polishing composition according to the present invention can be determined from the measurement with an atomic force microscope (AFM). The atomic force microscope is a microscope capable of measuring the interatomic force acting between a sample and a probe. Herein, when the same material and the same radius of curvature as those of the abrasives are adopted as the material and the radius of curvature of the probe tip portion, the probe tip portion can be regarded as the abrasive. Thus, when the same material and the same radius of curvature as those of the abrasives are adopted as the material and the radius of curvature of the probe tip portion, the interatomic force acting between the substrate surface and the abrasives can be measured. At this time, when the abrasives remain on the substrate surface, the force acting between the substrate surface or the like and the remaining abrasives also affects the measurement, making accurate measurement impossible. Thus, the measurement is performed with a substrate polished with a polishing composition free of the abrasives, i.e., the aqueous solution containing the adsorbing compound and water, as a target.

The adhesion force can be acquired from a force curve measured with the probe of the atomic force microscope. The force curve is a curve obtained by measuring force acting between a sample and the probe while the probe is being swept in the vertical (Z) direction near the sample, and plotting the distance between the probe and the sample on the horizontal axis and force acting on the probe on the vertical axis. Specifically, a force curve for the substrate polished using the aqueous solution containing the adsorbing compound and water was acquired, and, from the obtained force curve, the maximum attractive force immediately before the probe is separated from the substrate surface was defined as the adhesion force.

### (Method for Measuring Coverage)

The coverage can be acquired by the Adhesion measurement (adsorption force mode) of the atomic force microscope. The Adhesion measurement is a measurement method in which a sinusoidal contact motion between the probe and the sample is repeatedly performed on the sample surface while the atomic force microscope is scanned, and the deflection displacement measured at that time is imaged and acquired. Specifically, first, the average in-plane adhesion force of the substrate surface to which the adsorbing compound is not attached (hereinafter referred to as blank average adhesion force) is calculated. Next, the surface of the substrate polished with the aqueous solution containing the adsorbing compound and water is subjected to the Adhesion measurement, and binarization is performed with a part where the adhesion force is larger than the blank average adhesion force as a part covered with the adsorbing compound and with a part where the adhesion force is smaller than the blank average adhesion force as an uncovered substrate part. Finally, from the binarized image, the occupancy of the parts covered with the adsorbing compound in the entire substrate surface is calculated and defined as the coverage.

The adhesion force and the coverage can be appropriately controlled by selecting the type and the concentration of the adsorbing compound.

### (Liquid Medium)

The polishing composition according to this embodiment contains a liquid medium. The liquid medium functions as a dispersion medium or a solvent for dispersing or dissolving, respectively, components (abrasives, adsorbing compound, and, as required, additives, such as pH adjusters) of the polishing composition. The liquid medium includes water and organic solvents. One type of the liquid media can be used alone or two or more types thereof can be used as a mixture, and the liquid medium preferably contains water. However, from the viewpoint of preventing the inhibition of the action of each component, water containing as little impurities as possible is preferably used. Specifically, pure water or ultrapure water obtained by removing impurity ions with an ion exchange resin, and then removing contaminants through a filter, or distilled water is preferable.

### (pH of Polishing Composition)

The pH of the polishing composition according to this embodiment is 1 or more and 6 or less. Within such a range, the polishing removal rate of the simple-substance silicon can be adjusted while films of other species, such as silicon oxide and silicon nitride, are polished at high speed. The pH of the polishing composition according to this embodiment may be 1.5 or more, may be 1.8 or more, or may be 2 or more. The pH of the polishing composition may be 5 or less, may be 4 or less, or may be 3 or less. The pH of the polishing composition can be measured by the method described in Examples.

The polishing composition according to this embodiment may contain a pH adjuster to adjust the pH in the ranges described above. The pH adjuster to be used may be acids, bases, or both of them and may be inorganic compounds, organic compounds, or both of them.

Specific examples of the acids as the pH adjuster include inorganic acids or organic acids. Specific examples of the inorganic acids include sulfuric acid, nitric acid, boric acid, carbonic acid, hypophosphorous acid, phosphorous acid, phosphoric acid, and the like. As the pH adjuster, the inorganic acids are preferably used. Among the inorganic acids, sulfuric acid and nitric acid are more preferable, and nitric acid is particularly preferable. The organic acids include carboxylic acids and organic sulfuric acids. Specific examples of the carboxylic acids include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, and the like. Specific examples of the organic sulfuric acids include methanesulfonic acid, ethanesulfonic acid, isethionic acid, and the like. One type of these acids may be used alone or two or more types thereof may be used in combination. These acids may be contained as the pH adjuster in the polishing composition, may be contained as an additive for improving the polishing removal rate, or may be contained as both of the pH adjuster and the additive in combination.

Specific examples of the bases as the pH adjuster include alkali metal hydroxides or salts thereof, alkaline earth metal hydroxides or salts thereof, quaternary ammonium hydroxides or salts thereof, ammonia, amine, and the like. Specific examples of the alkali metals include potassium, sodium, and the like. Specific examples of the alkaline earth metals include calcium, strontium, and the like. Specific examples of the salts include carbonates, hydrogen carbonates, sulfates, acetates, and the like. Specific examples of the quaternary ammonium include tetramethylammonium, tetraethylammonium, tetrabutylammonium, and the like.

Quaternary ammonium hydroxide compounds include quaternary ammonium hydroxides or salts thereof. Specific examples include tetramethylammonium hydroxide, tetraethylammonium hydroxide, tetrabutylammonium hydroxide, and the like. Specific examples of the amines include methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, anhydrous piperazine, piperazine hexahydrate, 1-(2-aminoethyl)piperazine, N-methylpiperazine, guanidine, and the like. One type of the bases may be used alone or two or more types thereof may be used in combination.

### (Other Additives)

The polishing composition according to one aspect of the present invention may further contain known additives, such as chelating agents, oxidants, thickeners, dispersants, surface protectants, wetting agents, and dissolution aids, to such an extent that the effects of the present invention are not impaired. The content of the additive above may be set as appropriate according to the purpose of the addition of the additives.

### <Polishing Composition Production Method>

A polishing composition production method according to one aspect of the present invention is not particularly restricted, and the polishing composition can be obtained by stirring and mixing the abrasives, the adsorbing compound, and, as required, the other additives in the liquid medium, for example. The temperature in the mixing of each component is not particularly restricted, and is preferably 10° C. or more and 40° C. or less, and heating may be performed to increase the dissolution rate. The mixing time is also not particularly restricted insofar as the components can be homogeneously mixed.

### <Polishing Method>

A polishing method according to the embodiment of the present invention enables polishing of the object to be polished using the polishing composition according to the present invention.

The configuration of a polishing device is not particularly limited. For example, common polishing devices are usable which include a holder holding a substrate or the like having the object to be polished, a drive unit, such as a motor having a changeable rotation speed, and a polishing platen to which a polishing pad can be attached. As the polishing pad, common non-woven fabrics, polyurethane, porous fluororesin, and the like are usable without being particularly restricted. As the polishing pad, those subjected to grooving such that a liquid polishing composition stays are usable.

The polishing conditions are not particularly restricted, and the rotation speed of the polishing platen is preferably 10 rpm (0.17 s⁻¹) or more and 500 rpm (8.3 s⁻¹) or less, for example. The pressure applied to the substrate (polishing pressure) having the object to be polished is preferably 0.5 psi (3.4 kPa) or more and 10 psi (68.9 kPa) or less. A method for supplying the polishing composition to the polishing pad is also not particularly restricted, and a method for continuously supplying the polishing composition with a pump or the like is adopted. The supply amount is not restricted, and the surface of the polishing pad is preferably constantly covered with the polishing composition according to one aspect of the present invention.

The polishing composition according to this embodiment may be a one-component type or a multi-component type including a two-component type. The polishing composition may also be prepared by diluting a liquid concentrate of the polishing composition to, for example, 10-fold or more, using a diluent such as water.

After the polishing, the substrate is cleaned with running water, for example, and dried by removing water droplets attached onto the substrate with a spin dryer or the like, thereby giving the substrate having a layer containing a silicon-containing material, for example. Thus, the polishing composition according to the embodiment of the present invention is usable in application of polishing the substrate. The surface of the object to be polished provided on a semiconductor substrate is polished using the polishing composition according to the embodiment of the present invention, whereby the surface of the semiconductor substrate is polished at high polishing removal rate, so that the polished semiconductor substrate can be produced. The semiconductor substrate includes, for example, silicon wafers having layers containing the simple-substance silicon, silicon compound, metal, and the like.

### EXAMPLES

Hereinafter, Examples and Comparative Examples of the present invention are described, but the present invention is not limited to Examples described below. In Examples described below, a technically preferable limitation is made to implement the present invention, but this limitation is not a requirement of the present invention. Examples described below can be variously altered or modified, and such altered or modified aspects may also be included in the present invention.

### Preparation of Polishing Composition

### Example 1

Colloidal silica particles (average primary particle diameter: 12 nm, average secondary particle diameter: 35 nm) as the abrasives, a butenediol-polyvinyl alcohol copolymer (BVOH) as the adsorbing compound, nitric acid as the pH adjuster, and water as the liquid medium were stirred and mixed, preparing a polishing composition having a concentration of the butenediol-polyvinyl alcohol copolymer of 40 ppm. The silica concentration in the polishing composition was set to 5% by mass, and the pH was adjusted to 2.5.

The pH was measured with a pH meter (product name: LAQUA (registered trademark) manufactured by HORIBA, Ltd.).

### Comparative Example 1

A polishing composition of Comparative Example 1 was prepared in the same manner as in Example 1, except that the adsorbing compound was not added.

### Examples 2 to 12, Comparative Examples 2 to 5

Polishing compositions of Examples 2 to 12, Comparative Examples 2 to 5 were prepared in the same manner as in Example 1, except for changing the type and the concentration of the adsorbing compound as shown in Table 1.

### <Measurement of Polishing Removal Rate>

Using the polishing compositions of Examples 1 to 12, Comparative Examples 1 to 5, a 60 mm square silicon wafer (silicon wafer with a polysilicon film) on the surface of which a 5000 Å thick polysilicon film was formed was polished under the following polishing conditions.
Polishing device: Tabletop polishing machine EJ-380IN manufactured by ENGIS JAPAN
Polishing pad: Rigid polyurethane pad IC1000, XY groove manufactured by Nitta-Haas Co.
Polishing pressure: 2.25 psi (1 psi=6894.76 Pa)
Polishing platen rotation speed: 50 rpm
Head rotation speed: 50 rpm
Supply of polishing composition: One-way
Polishing composition supply rate: 100 mL/min
Polishing time: 60 seconds

The silicon wafer with a polysilicon film was measured for each of the film thickness before the polishing and the film thickness after the polishing using an optical interferometry film thickness measurement system, Lambda Ace VM-2030 (manufactured by SCREEN). Then, the polishing removal rate was calculated from the film thickness difference and the polishing time. The results are shown in Table 1.

TABLE 1

| | | | | | Polysilicon | | | |
|---|---|---|---|---|---|---|---|---|
| | | | | | film | | | |
| | | | | | polishing | | | |
| | Abrasives | | Adsorbing compound | | removal | Adhesion | | Adhesion |
| | | Concentration | | Concentration | rate | force | Coverage | force × |
| | Type | [% by mass] | Type | [ppm] | [Å/min] | [nN] | [%] | Coverage |
| Comp. | Silica | 5.0 | None | 0 | 27 | 3.53 | 0 | 0.0 |
| Ex. 1 | | | | | | | | |
| Comp. | Silica | 5.0 | Butenediol- | 10 | 182 | 1.85 | 58 | 107.0 |
| Ex. 2 | | | polyvinyl alcohol | | | | | |
| | | | copolymer | | | | | |
| Ex. 1 | Silica | 5.0 | Butenediol- | 40 | 261 | 1.22 | 80 | 97.6 |
| | | | polyvinyl alcohol | | | | | |
| | | | copolymer | | | | | |
| Ex. 2 | Silica | 5.0 | Butenediol- | 70 | 426 | 1.03 | 91 | 93.9 |
| | | | polyvinyl alcohol | | | | | |
| | | | copolymer | | | | | |
| Ex. 3 | Silica | 5.0 | Butenediol- | 100 | 523 | 0.81 | 99 | 79.8 |
| | | | polyvinyl alcohol | | | | | |
| | | | copolymer | | | | | |
| Ex. 4 | Silica | 5.0 | Butenediol- | 500 | 361 | 0.63 | 98 | 61.8 |
| | | | polyvinyl alcohol | | | | | |
| | | | copolymer | | | | | |
| Ex. 5 | Silica | 5.0 | Butenediol- | 1500 | 268 | 0.53 | 99 | 52.8 |
| | | | polyvinyl alcohol | | | | | |
| | | | copolymer | | | | | |
| Comp. | Silica | 5.0 | Butenediol- | 10000 | 164 | 1.23 | 98 | 120.7 |
| Ex. 3 | | | polyvinyl alcohol | | | | | |
| | | | copolymer | | | | | |
| Comp. | Silica | 5.0 | Polyvinyl alcohol | 10 | 140 | 2.05 | 58 | 118.9 |
| Ex. 4 | | | | | | | | |
| Ex. 6 | Silica | 5.0 | Polyvinyl alcohol | 100 | 402 | 0.90 | 99 | 88.7 |
| Ex. 7 | Silica | 5.0 | Polyvinyl alcohol | 500 | 278 | 0.65 | 98 | 63.8 |
| Ex. 8 | Silica | 5.0 | Polyvinyl alcohol | 1500 | 206 | 0.55 | 95 | 52.0 |
| Comp. | Silica | 5.0 | Polyvinyl alcohol | 10000 | 126 | 1.37 | 98 | 134.1 |
| Ex. 5 | | | | | | | | |
| Ex. 9 | Silica | 5.0 | Polyacrylic acid | 80 | 228 | 1.31 | 75 | 98.3 |
| Ex. 10 | Silica | 5.0 | Polyacrylic acid | 20 | 331 | 0.72 | 91 | 65.5 |
| Ex. 11 | Silica | 5.0 | Carboxymethyl | 100 | 354 | 1.14 | 85 | 96.9 |
| | | | cellulose | | | | | |
| Ex. 12 | Silica | 5.0 | Carboxymethyl | 200 | 283 | 0.65 | 91 | 59.2 |
| | | | cellulose | | | | | |

### <Evaluation of Adhesion Force and Coverage>

The adhesion force and the coverage of the polishing composition of each of Examples 1 to 12 and Comparative Examples 1 to 5 were determined by measurement with an atomic force microscope S-image/NanoNavi2 manufactured by SII⋅NanoTechnology Inc. As the material and the radius of curvature of a probe tip portion, the same material and the same radius of curvature as those of the abrasives were adopted. Thus, the tip portion of the probe can be regarded as the abrasive. Accordingly, the measurement can be performed taking force acting between the substrate surface and the probe tip portion as force acting between the substrate surface and the abrasives.

First, a mixed liquid was prepared in the same manner as in Examples 1 to 12 and Comparative Examples 1 to 5, except that the mixed liquid was free of the abrasives, i.e., the aqueous solution containing the adsorbing compound and water. Next, the polishing was performed in the same manner as in <Measurement of polishing removal rate>, except that these mixed liquids were used. The reason for using such a mixed liquid is that, when a substrate is polished using the polishing composition containing the abrasives, the abrasives remain on the substrate surface, and the force acting between the substrate surface or the like and the remaining abrasives also affects the measurement, making accurate measurement of the adhesion force and the coverage impossible.

### (Method for Measuring Adhesion Force)

For the silicon wafers with a polysilicon film after measured for the adhesion force, force curves were individually acquired using the probe of the atomic force microscope. Thereafter, the maximum attractive force immediately before the probe was separated from the substrate surface is defined as the adhesion force based on the obtained force curves. The results are shown in Table 1.

The probe and the measurement conditions used for the measurement of the adhesion force are as described below.
Probe: qp-BioAC-Cl_CB3 manufactured by Nanosensors
Scanning frequency: 1 Hz
Scanning range: −5 nm to 300 nm

### (Method for Measuring Coverage)

The average in-plane adhesion force of the substrate surface to which the adsorbing compound was not attached (hereinafter referred to as blank average adhesion force) was calculated using the atomic force microscope. Then, the surface of the substrate polished with the aqueous solution containing the adsorbing compound and water was subjected to the Adhesion measurement using the atomic force microscope to image the deflection displacement. Binarization was performed with a part where the adhesion force is larger than the blank average adhesion force as a part covered with the adsorbing compound and with a part where the adhesion force is smaller than the blank average adhesion force as an uncovered substrate part, of the obtained image. Finally, from the binarized image, the occupancy of the parts covered with the adsorbing compound in the entire substrate surface was calculated and defined as the coverage. The results are shown in Table 1.

The probe and the measurement conditions used for the measurement of the coverage are as described below.
Probe: qp-CONT manufactured by nanosensors
Measurement range: 500 nm×500 nm
Stage amplitude: 30 nm
Stage frequency: 1 kHz

### (Evaluation of Adhesion Force×Coverage)

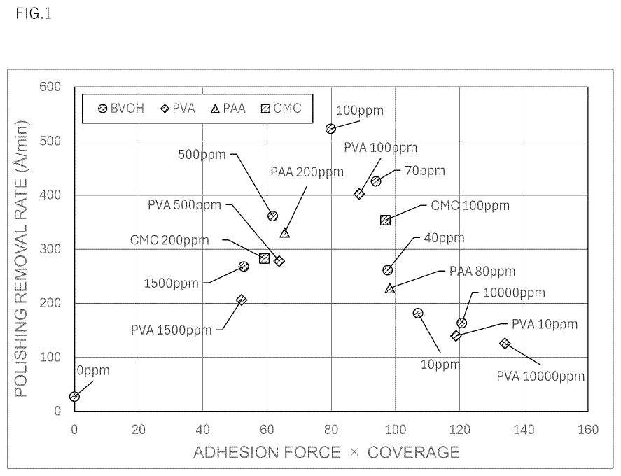

Further, from the obtained adhesion force and coverage of each of Examples 1 to 12 and Comparative Examples 1 to 5, values obtained by multiplying the adhesion force and the coverage were determined. The results are shown in Table 1. The results of Examples 1 to 12 and Comparative Examples 1 to 5 are illustrated in FIG. 1, in which the value obtained by multiplying the adhesion force and the coverage is plotted on the horizontal axis and the polishing removal rate is plotted on the vertical axis.

### <Evaluation>

As shown in Table 1, the results were such that Examples 1 to 12 all had the polishing removal rate for polysilicon of 200 Å/min or more and Comparative Examples 1 to 5 all had the polishing removal rate for polysilicon of less than 200 Å/min. This showed that the polishing removal rate of polysilicon is higher in Examples 1 to 12 than in Comparative Examples 1 to 5.

The results of Examples 1 to 8 and Comparative Examples 1 to 5 showed that, when a butenediol-polyvinyl alcohol copolymer or polyvinyl alcohol was used as the adsorbing compound, the polishing removal rate tends to increase with an increase in coverage. The results of Comparative Examples 3 and 5 showed that, when the concentration of the adsorbing compound contained in the polishing composition increases, the coverage is improved, but the adhesion force increases and the polishing removal rate also decreases. This is considered to be because the amount of the adsorbing compound contained in the polishing composition became excessive, making it for the abrasives difficult to roll over the substrate surface.

As illustrated in FIG. 1, it was found that, when the value obtained by multiplying the adhesion force and the coverage is 50 or more and less than 100, the polishing removal rate for the polysilicon film is 200 Å/min or more irrespective of the type of the adsorbing compound. This showed that, even in the case of an acidic polishing composition, when the value obtained by multiplying the adhesion force and the coverage is 50 or more and less than 100, the polishing removal rate of the polysilicon film is improved. This is considered to be because, when the value obtained by multiplying the adhesion force and the coverage falls within the ranges above, the attachment force to the substrate of the abrasives becomes an appropriate value for polishing.

The present invention can also take the following configurations, for example.

[1]

A polishing composition, which is a polishing composition for polishing simple-substance silicon, containing:
abrasives; and an adsorbing compound, in which
the pH is 1 or more and 6 or less,
when a substrate having a surface containing simple-substance silicon is subjected to polishing of the surface using an aqueous solution containing the adsorbing compound and water, and then the adhesion force of the abrasives to the surface of the polished substrate and the coverage of the adsorbing compound are measured, a value obtained by multiplying the adhesion force and the coverage is more than 50 and less than 100,
   the adhesion force is attachment strength between the abrasives and the surface of the substrate calculated by the force curve measurement using a probe provided in an atomic force microscope,
the probe contains the same material as that of the abrasives and has a tip portion having the same radius of curvature as that of the abrasives, and
the coverage is the ratio of the area of a part covered with the adsorbing compound of the surface of the substrate to the area of the entire surface of the substrate.
   [2]

The polishing composition according to [1], in which the adsorbing compound is at least one of a water-soluble polymer and a surfactant.

[3]

The polishing composition according to [1] or [2], in which the adsorbing compound has at least one selected from the group consisting of a hydroxy group, a carbonyl group, a sulfo group, and an amide group.

[4]

The polishing composition according to any one of [1] to [3], in which the adsorbing compound is at least one selected from the group consisting of a butenediol-vinyl alcohol copolymer, polyvinyl alcohol, polyacrylic acid, carboxymethylcellulose, polystyrenesulfonic acid, poly-N-vinyl acetamide, polyvinylpyrrolidone, hydroxyethylcellulose, and polyacrylamide.

[5]

The polishing composition according to any one of [1] to [4], in which the pH is 2 or more and 5 or less.

[6]

The polishing composition according to any one of [1] to [5], in which the abrasive is silica.

[7]

The polishing composition according to [6], in which the silica is anion-modified silica.

[8]

A polishing method includes: polishing simple-substance silicon using the polishing composition according to any one of [1] to [7].

1. A polishing composition,
the polishing composition being a polishing composition for polishing simple-substance silicon, comprising:
abrasives; and
an adsorbing compound, and
wherein
a pH is 1 or more and 6 or less,
when a substrate having a surface containing simple-substance silicon is subjected to polishing of the surface using an aqueous solution containing the adsorbing compound and water, and then adhesion force of the abrasives to the surface of the polished substrate and a coverage of the adsorbing compound are measured, a value obtained by multiplying the adhesion force and the coverage is more than 50 and less than 100,
the adhesion force is attachment strength between the abrasives and the surface of the substrate calculated by force curve measurement using a probe provided in an atomic force microscope,
the probe contains a same material as a material of the abrasives and has a tip portion having a same radius of curvature as a radius of curvature of the abrasives, and
the coverage is a ratio of an area of a part covered with the adsorbing compound of the surface of the substrate to an area of an entire surface of the substrate.

2. The polishing composition according to claim 1, wherein the adsorbing compound is at least one of a water-soluble polymer and a surfactant.

3. The polishing composition according to claim 1, wherein the adsorbing compound has at least one selected from the group consisting of a hydroxy group, a carbonyl group, a sulfo group, and an amide group.

4. The polishing composition according to claim 1, wherein the adsorbing compound is at least one selected from the group consisting of a butenediol-vinyl alcohol copolymer, polyvinyl alcohol, polyacrylic acid, carboxymethylcellulose, polystyrenesulfonic acid, poly-N-vinyl acetamide, polyvinylpyrrolidone, hydroxyethylcellulose, and polyacrylamide.

5. The polishing composition according to claim 1, wherein the pH is 2 or more and 5 or less.

6. The polishing composition according to claim 1, wherein the abrasive is silica.

7. The polishing composition according to claim 6, wherein the silica is anion-modified silica.

8. A polishing method comprising:
polishing simple-substance silicon using the polishing composition according to claim 1.

9. The polishing composition according to claim 2, wherein the adsorbing compound has at least one selected from the group consisting of a hydroxy group, a carbonyl group, a sulfo group, and an amide group.

10. The polishing composition according to claim 2, wherein the adsorbing compound is at least one selected from the group consisting of a butenediol-vinyl alcohol copolymer, polyvinyl alcohol, polyacrylic acid, carboxymethylcellulose, polystyrenesulfonic acid, poly-N-vinyl acetamide, polyvinylpyrrolidone, hydroxyethylcellulose, and polyacrylamide.

11. The polishing composition according to claim 2, wherein a pH is 2 or more and 5 or less.

12. The polishing composition according to claim 2, wherein a abrasive is silica.

13. The polishing composition according to claim 12, wherein the silica is anion-modified silica.

14. A polishing method comprising:
polishing simple-substance silicon using the polishing composition according to claim 2.
